(19) United States
(12) Patent Application Publication
(10) Pub. No.: US 2008/0211080 A1
(43) Pub. Date: Sep. 4, 2008

(54) Package structure to improve the reliability for WLP

(75) Inventors: Wen-Kun Yang, Hsin-Chu City (TW); Diann-Fang Lin, Hukou Township (TW)

Correspondence Address: BIRCH STEWART KOLASCH & BIRCH, PO BOX 747, FALLS CHURCH, VA, 22040-0747, US

(73) Assignee: Advanced Chip Engineering Technology Inc.

(21) Appl. No.: 11/712,365

(22) Filed: Mar. 1, 2007

(51) Int. Cl. H01L 23/48

(52) U.S. Cl. 257/690; 257/E23.01

(57) ABSTRACT

The present invention provides a package structure to improve the reliability for WLP (Wafer Level Package). The package structure includes at least two areas. One area is harder than another. The hard area sustains more shears resulting from board drop test than the soft area in order to disperse the shear in the soft area to avoid the peeling of the buffer layers within the soft area.

### BACKGROUND OF THE INVENTION

1. Field of the Invention

The present invention relates to package structures, and in particularly to package structure to improve the reliability for WLP.

2. Description of the Prior Art

In semiconductor device assembly, a semiconductor chip (also referred to as an integrated circuit (IC) chip or “die”) may be bonded directly to a packaging substrate, without the lead-frame or bonding wire. Such chips are formed with ball-shaped beads or bumps of solder affixed to their I/O bonding pads.

In a conventional method for packaging a semiconductor die and a packaging substrate are electrically connected and mechanically bonded in a solder joining operation. The die is aligned with and placed onto a placement site on the packaging substrate such that the die's solder balls are aligned with electrical pads or pre-solder on the substrate. The substrate is typically composed of an organic material or laminate. Heat is applied causing the solder balls to alloy and form electrical connections between the die and the packaging substrate. The package is then cooled to harden the connection.

Semiconductor packages are typically subject to temperature cycling during normal operation. In order to improve the thermal performance and reliability of the packages, buffer layers are often used. The purpose of the buffer layers is to constrain the substrate in order to prevent its warpage or other movement relative to the die which may be caused by thermal cycling during operation of an electronic device in which the package is installed. Such movement may result from the different coefficients of thermal expansion (CTE) of the die and substrate materials, and may produce stress in the die or the package as a whole which can result in electrical and mechanical failures. The purpose of the buffer layers is to reduce stress in the package due to different CTEs of the various elements of the package, including the die, substrate.

A problem with such package constructions is that during the cool down from the temperature for solder join, the whole package suffers highly stress due to the different coefficients of thermal expansion (CTEs) between the substrate and die materials. The high stress experienced by these bonded materials during cooling down procedure may cause them to warp or crack, thereby resulting the package malfunction.

Additionally, the buffer layers are under the solder balls area, when the package is dropped, it is unlikely to suffer the impact. It results that the buffer layers are peeling due to the ball shear strength of the solder balls higher than the one of the buffer layers. Accordingly, what is needed is an advanced package and the method of the same to improve reliability.

### SUMMARY OF THE INVENTION

To achieve the forgoing, the present invention discloses a package structure with solder balls to attach (soldering join) on the print circuit board to improve the reliability for WLP (Wafer Level Package), the package comprises a soft area located outside distance from neutral point (DNP) of the package structure, the soft area has elastic dielectric layers to absorb thermal stress. A hard area is located within the DNP of the package structure, wherein material of the dielectric layers within the hard area is more hard than the soft area. The DNP can be defined that base on the distance, the size of solder balls and the open size of metal pads.

An aspect of the present invention is that the scope area within distance from neutral point (DNP) on the chip doesn't need the protection of buffer layers due to the stress resulting from coefficient of thermal expansion (CTE) not effecting the area within DNP, therefore, merely adding the buffer area outside the DNP area to reduce the stress in the package structure of WLP due to the different CTEs of the various elements of the package, for example, the substrate, the die, the solder balls, the dielectric layers (DL), or the redistribution layers (RDL).

Furthermore, the material of dielectric layer area within DNP is selected from the materials harder than the outside DNP to enhance the holding force between the solder balls of the package structure and the board. Thus, the area within DNP can sustain more stress resulting from dropping on the ground so that prevent the buffer layers from peeling to improve the reliability of the package structure for WLP.

### BRIEF DESCRIPTION OF THE DRAWINGS

The above objects, and other features and advantages of the present invention will become more apparent after reading the following detailed description when taken in conjunction with the drawings, in which:

FIG. 1 depicts a top view of a semiconductor package structure to improve the reliability for WLP (Wafer Level Package) in accordance with the embodiment of the present invention.

FIG. 2 depicts a side view of a semiconductor package structure to improve the reliability for WLP attached to the print circuit board to experiment on board drop test in accordance with another embodiment of the present invention.

### DESCRIPTION OF THE PREFERRED EMBODIMENT

The following embodiments and drawings thereof are described and illustrated in the specification that are meant to be exemplary and illustrative, not limiting in scope. One skilled in the relevant art will identify that the invention may be practiced without one or more of the specific details, not limiting in scope.

Referenced throughout the specification to “one embodiment” or “an embodiment” means that a particular feature, structure, or characteristic described in connection with the embodiment and included in at least one embodiment of the present invention. Thus, the appearances of the phrase “in one embodiment” or “in an embodiment” in various places throughout the specification are not necessarily all referring to the same embodiment. Furthermore, the particular features, structures, or characteristics may be combined in any suitable manner in one or more embodiments.

The present invention provides a semiconductor package structure to improve the reliability for WLP (Wafer Level Package). The principle of the present invention is that the scope area within distance from neutral point (DNP) on the chip doesn't need the protection of buffer layers due to the stress resulting from coefficient of thermal expansion (CTE) not effecting the area within DNP, therefore, merely adding the buffer area outside the DNP area to reduce the stress in the package structure of WLP due to the different CTEs of the various elements of the package, for example, the substrate, the die, the solder balls, the dielectric layers (DL), or the redistribution layers (RDL). Furthermore, the material of dielectric layer area within DNP is selected from the materials that are harder than the one outside DNP to enhance the adhesion between the solder balls of the package and the board.

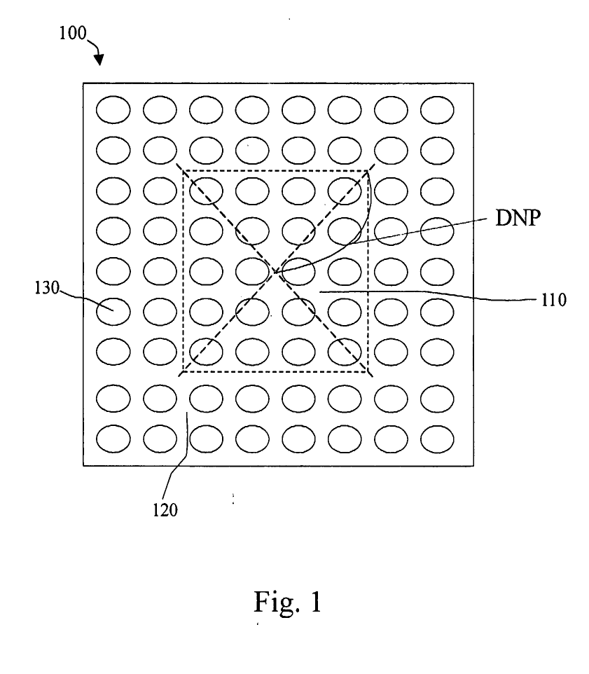

In an embodiment, as shown in FIG. 1, it depicts a top view of a semiconductor package structure to improve the reliability for WLP (Wafer Level Package). A package structure 100 of wafer level package having the solder balls (bumps) 130 formed thereon includes at least two areas consisting of a hard area 110 and a soft area 120. The area surrounded by dotted line is the scope of the hard area 110 which is defined by DNP. The length of DNP is half diagonal of the dotted area. Carefully, the distributions of the scopes in soft area 120 and the hard area 110 as shown in FIG. 1 are not fixed, the embodiment only for illustrating.

The hard area 110 is designated at the inner area of the chip and within the DNP on the package structure 100 of WLP. The hard area is within the maximum area of DNP. The range of the DNP depends on the result of temperature coefficient (TC) test, and it relative to the size of solder ball and opening size of contact metal pads. In the preferably embodiment, the DNP is around 3-4 mm for 0.3 mm solder ball size.

In the hard area 110, the CTE of the dielectric layers (not shown) on the dies of the semiconductor package 100 are in the range of about 20-80 ppm, and the hardness of the dielectric layers is substantially the same as the one of the plastic (epoxy type), the percentage elongation of the dielectric layers is less than 10%. Additionally, the materials of dielectric layers have a good adhesion with silicon nitride and Polyimide (PI), and good adhesion with RDL metal and seed metal layers through the sputter process by using higher power. In the embodiment, the material of the dielectric layers is Benzocyclobutene (BCB) or Polyimide (PI), and the process forming dielectric layers can be performed either on the wafer before dicing wafer or after. The top dielectric layer on the dies of package structure 100 may be elastic materials. The ball shear strength of the hard area 110 is in the range of around 300-400 gm for 0.3 mm ball size, moreover, the solder balls 130 within hard area 110 are solid soldered to join with the print circuit board (PCB) so as to enhance the holding force there in before.

Please refer to the soft area 120, the area 120 may be on the chip area of package structure 100 except the hard area 110, therefore, the area scope are large than DNP area, and maybe located on the core paste area to absorb the stress in the package structure 100 of WLP due to the different CTEs of the various elements of the package 100, for example, the substrate, the die, the solder balls, the dielectric layers (DL), or the redistribution layers (RDL). The dielectric layers (not shown) of soft area 120 are located on the surface of dies within the package structure 100. The materials of dielectric layers having the CTE large than 100 ppm, have a good adhesion with silicon nitride, BCB and PI, but poor adhesion with metal layers. The elastic property of materials of dielectric layers is extending in range of about 30-50%, and the hardness of the dielectric layers is between rubber and plastic. Additionally, the materials of dielectric layers have poor adhesion with seed metal layer formed under solder balls 130 through during sputtering by using lower power. In the embodiment, the material of dielectric layers is Silicone based dielectrics—Siloxane Polymer (SINR) or Dow Corning WL5000/3000 series and the ball shear strength of the soft area 120 is around 80-120 gm for 0.3 mm ball size. Additionally, the solder balls 130 within the soft area 120 are joined with PCB by floating soldering because the material of dielectric layers within the soft area 120 is elastic.

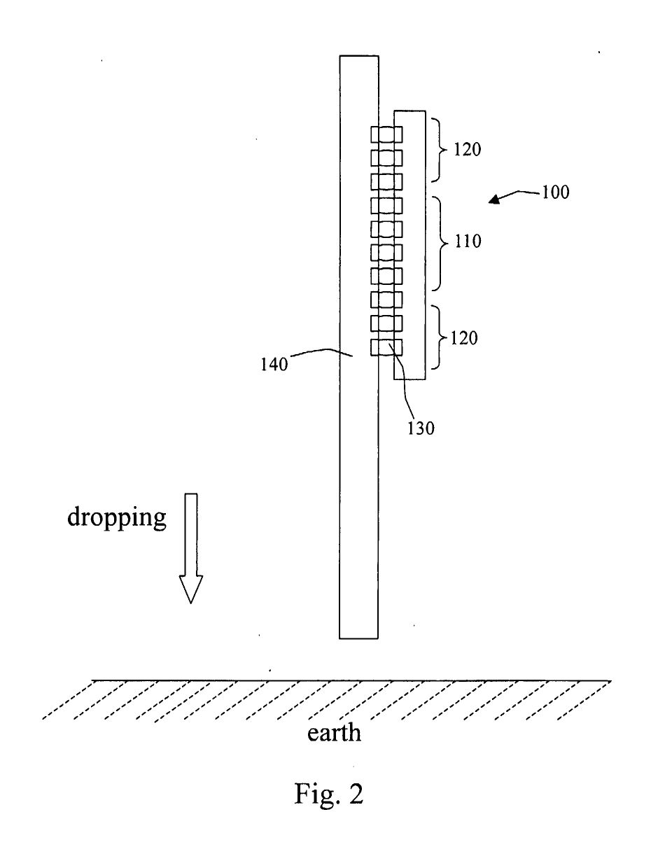

As shown in FIG. 2, it depicts a side view of a semiconductor package structure 100 to improve the reliability for WLP attached to the PCB 140 to experiment on board drop test in accordance with another embodiment of the present invention. The package structure 100 with print circuit board is drop on the ground to determine whether the elastic dielectric layers (buffer layer) under the solder balls 130 will be peel or not when the buffer layers suffer the instant shear.

The package structure 100 having the solder balls 130 formed thereon includes at least two areas consisting of the hard area 110 and the soft area 120. The solder balls 130 within hard area 110 are solid soldered with the PCB 140 by connecting contact pads (UBM) to land pads of PCB through the solder balls 130 so as to enhance the holding force therebetween. On the contrary, the solder balls 130 within the soft area 120 are joined with PCB 140 by “floating soldering” because the material of dielectric layers within the soft area 120 is elastic to reduce the die/substrate CTE mismatch.

The ball shear strength of the soft area 120 with a buffer releasing structure (elastic dielectric layers) is about 100 gm, and the ball shear strength of the hard area 110 without the elastic dielectric layers is more than 300 gm for suffering the shear generated from board drop test to prevent the buffer layers (elastic dielectric layers) from peeling. When the PCB 140 soldering with the package structure 100 is dropping on the ground, the hard area 110 bears the majority of instant shear to protect the package structure 100 from peeling. Therefore, the package reliability is thereby enhanced.

It will be appreciated to those skilled in the art that the preceding examples and preferred embodiments are exemplary and not limiting to the scope of the present invention. It is intended that all permutations, enhancements, equivalents, and improvements thereto that are apparent to those skilled in the art upon a reading of the specification and a study of the drawings are included within the true spirit and scope of the present invention.

What is claimed is:

1. A package structure to improve the reliability, comprising:
a soft area located outside DNP (distance from neutral point) of said package structure, wherein said soft area has a first dielectric layer to absorb thermal stress; and
a hard area located within said DNP of said package structure, wherein material of a second dielectric layer within said hard area is harder than the one of said first dielectric layer.

2. The structure in claim 1, wherein maximum area of said hard area inside said DNP on said package structure is dependent on the dimensions of said DNP.

3. The structure in claim 1, wherein said DNP is around 3-4 mm for 0.3 mm solder ball size.

4. The structure in claim 1, wherein said second dielectric layer within said hard area includes redistribution layer (RDL) or seed metal layer of said package structure.

5. The structure in claim 1, wherein CTE of said material of said second dielectric layers within said hard area is in range of 20-80 ppm.

6. The structure in claim 1, wherein said package structure is attached on a PCB by soldering with said PCB through solder balls so as to enhance the holding force there in before.

7. The structure in claim 1, wherein said second dielectric layer has a good adhesion with silicon nitride and Polyimide (PI).

8. The structure in claim 1, wherein the percentage elongation of said material of said second dielectric layer within said hard area is less than 10%.

9. The structure in claim 4, wherein said material of said second dielectric layer within said hard area has a good adhesion with said seed metal layers through the sputtering process using higher power.

10. The structure in claim 1, wherein said material of said second dielectric layer within said hard area is Benzocyclobutene (BCB), Polyimide (PI).

11. The structure in claim 1, wherein ball shear strength of said hard area is large than the ball shear strength of said soft area.

12. The structure in claim 1, wherein said soft area is located on the area except said hard area.

13. The structure in claim 1, wherein said soft area is large than said hard area.

14. The structure in claim 1, wherein said first dielectric layer within said soft area has a good adhesion with silicon nitride and PI/BCB.

15. The structure in claim 1, wherein the percentage elongation of said first dielectric layer within said soft area is about in the range of 30-50%.

16. The structure in claim 1, wherein the CTE of said dielectric layers within said soft area is larger than 100.

17. The structure in claim 1, wherein said first dielectric layer within said soft area has poor adhesion with seed metal layers of said package structure through during sputtering by using lower power.

18. The structure in claim 1, wherein said first dielectric layers within said soft area is Silicone based dielectrics—Siloxane Polymer (SINR), Dow Corning WL5000/3000 series.
